(19) United States
(12) Patent Application Publication
(10) Pub. No.: US 2002/0100557 A1
(43) Pub. Date: Aug. 1, 2002

(54) ICP window heater integrated with faraday shield or floating electrode between the source power coil and the ICP window

(75) Inventors: Maocheng Li, Fremont, CA (US); John Holland, San Jose, CA (US); Valentin N. Todorov, Fremont, CA (US); Patrick Leahey, San Jose, CA (US); Robert P. Hartlage, San Jose, CA (US); Hoan Hai Nguyen, Milpitas, CA (US)

Correspondence Address: Patent Counsel, Legal Affairs Dept. MS/2061, Applied Materials, Inc., P.O. Box 450A, Santa Clara, CA, 95052, US

(73) Assignee: Applied Materials, Inc.

(21) Appl. No.: 09/774,192

(22) Filed: Jan. 29, 2001

(51) Int. Cl. C23F 1/00; C23C 16/00

(52) U.S. Cl. 156/345.48; 156/345.37; 118/724; 118/723 I; 118/666

(57) ABSTRACT

A method and an apparatus that provides efficient heating of a dielectric structure without compromising the dielectric properties of the structure. A heating assembly is adapted to fit a circularly shaped dielectric lid of a plasma processing vacuum chamber. The heating assembly is placed between the RF coil and the atmospheric side of the dielectric lid. Although the active heating structure portion (a resistive heating wire or a thermal working fluid or both, per alternate embodiments) of the heating assembly is transparent to the electromagnetic fields produced by the coil, the conductive portion of the heating assembly takes on the role of shaping the electric field. The result of this averaging is the minimization of detrimental effects of electromagnetic potentials that are too high (e.g., sputtering of the dielectric by the plasma) and of electromagnetic potentials that are too low (e.g., heavy by-product depositions on the dielectric lid).

### BACKGROUND OF THE INVENTION

The present invention relates generally to the field of semiconductor processing chambers. More particularly, the present invention relates to an apparatus for regulating the temperature of the lid of a semiconductor processing chamber.

It is advantageous to provide temperature control of structures used in plasma processing chambers. That is because of the temperature-dependent changes that occur in the chemical and physical properties of chamber materials, as well as any materials that may be present on the surface of the chamber structures. A significant concern in plasma semiconductor processing is controlling the generation of particulate. Particulate is commonly generated by a build up of various materials on the chamber surfaces that then has a tendency to flake off. The build up of material on the chamber surfaces is hastened if those chamber surfaces are relatively cool, which promotes sublimation of free molecules (ionized or neutral) onto the surfaces. Flaking off of the built up material is promoted by thermal cycling (repeated temperature swings), such as occurs when the plasma is repeatedly started and stopped as successive wafers are processed in the chamber. Thus, both coolness of chamber surfaces and thermal cycling of those surfaces contribute to formation of particulate in semiconductor processing chambers.

The formation of particulates can be suppressed to a certain extent by heating the chamber structures to a temperature higher than ambient. The higher temperature minimizes the formation of polymer films on the chamber surfaces and thereby minimizes the amount of particulate production. However, thermal cycling will still cause some amount of particulate to form by ensuring flaking of any film that does form on the chamber surfaces.

The chamber surface of most concern for particulate formation is the lid of the chamber because it is directly over the wafer. In the moments after the plasma is extinguished but before the wafer is removed from the chamber, the chamber lid begins to cool and any film that has formed on the lid begins to flake. Those particulate flakes will fall onto the wafer before it can make a clean exit from the chamber. Once the wafer has been removed, any particulate that continues to fall from the chamber lid will fall onto the chuck (or pedestal) where the wafers sit while being processed. Particulate landing on the chuck is an additional problem because it may cause the next wafer to have poor electrical contact with the chuck, which would result in an inadvertent modification of the process parameters. Thus, particulate on the chuck contributes to inconsistent production results.

Chamber lids are made from many materials, both conductive and non-conductive, depending on the type and design of the chamber. Dielectric materials are often chosen for use in inductively-coupled plasma processing chamber lids owing to their nonconductive properties. In the case of a dielectric lid of an inductively-coupled plasma processing chamber, the lid needs to be non-conductive so that it is transparent to the RF energy necessary for coupling into the chamber to induce a plasma cloud. Thus, any scheme for heating the dielectric structures must necessarily preserve that non-conducting behavior.

Unfortunately, heating of dielectric structure of a plasma chamber is often difficult. The dielectric materials commonly used in semiconductor processing vacuum chambers are aluminum-based ceramics and quartz. Both of these types of materials have poor thermal conductivities. The problem of heating a dielectric structure is compounded when it is a large item like the dielectric lids that cover the top of many plasma chambers.

Another feature that is often used in inductively-coupled plasma chambers is a Faraday shield, which is generally disposed between the chamber and the RF coil. The shield is used to control the transfer of electric field into the chamber. For more information the reader is directed to U.S. Pat. No. 4,918,031 to Flamm et al.

Thus, what is needed is an apparatus that heats dielectric structures of a processing chamber without detracting from the non-conductive nature of the dielectric structures. Preferably, the heater would be usable in conjunction with a Faraday shield.

### SUMMARY OF THE INVENTION

It is an aspect of the present invention to provide efficient heating of a plasma chamber structure.

It is another aspect of the present invention to provide a heating assembly arranged on the exterior surface of a plasma chamber lid.

It is another aspect of the present invention to provide an integrated heater and voltage distribution electrode assembly arranged on the surface of a plasma chamber lid.

It is another aspect of the present invention to provide efficient heating of a dielectric structure without compromising the dielectric properties of the structure.

It is another aspect of the present invention to provide a heating assembly arranged on the surface of a dielectric lid in such a way that its elements are perpendicular to the direction of an electromagnetic field that is directed through the dielectric lid.

It is yet another aspect of the present invention to provide a heating assembly having piecewise segments that are arranged in a radial manner, connected together by a circular loop portion having a diameter about the same as a dielectric lid on which it rests.

It is still another aspect of the present invention to provide a heating assembly having a circular loop portion that incorporates at least one gap to provide an electric break.

It is a further aspect of the present invention to provide a heating assembly for the dielectric lid of a plasma processing chamber that is substantially transparent to the RF field generated by the RF coil to generate a plasma inside the chamber.

It is an additional aspect of the present invention to provide heating of a dielectric vacuum chamber structure while simultaneously providing a voltage distribution or shielding functionality.

The present invention provides for a method and an apparatus that provides efficient heating of a dielectric structure without compromising the dielectric properties of the structure.

A heating assembly according to the preferred embodiment of the present invention is adapted to fit a circularly shaped lid of a plasma processing vacuum chamber. The assembly provides a distributed heater over the lid to evenly couple energy onto the lid. The heater is particularly advantageous when used over a dielectric lid of an inductively coupled chamber. In such an arrangement, the heating assembly is placed between the RF coil and the atmospheric side of the dielectric lid. The RF coil couples energy into the vacuum chamber to thereby excite the process gases inside the chamber into a plasma state. Since it is advantageous to minimize the separation of the coil and the ceramic lid, the heating assembly is designed to conform well to the surface of the dielectric lid and to be thin enough to not substantially increase the distance between the coil and the lid, while at the same time, providing uniform and efficient heating of the dielectric surface.

The bottom layer of the heater assembly according to the resistive heating embodiments is preferably constructed from a material that has good thermal conductivity such as aluminum or copper. A resistive heater wire (such as Nichrome wire) is attached to the bottom layer without being electrically connected thereto and is wound along the radial segments and connective circular loop in a manner which maximizes the electromagnetic resistance (i.e., impedance) of the overall heater wire circuit to the electromagnetic fields produced by the coil. A layer of thermal insulating material is placed on the surfaces of the heater elements. This insulating material improves the efficiency of the heater by minimizing heat losses to the ambient air. This insulation is particularly helpful for the embodiments that utilize forced air convection in order to remove excess heat from the surface of the dielectric lid.

According to an alternate embodiment, the heating assembly incorporates a fluid channel within the structure of the radial and loop elements. Temperature control of the dielectric lid is achieved in this embodiment by forcing a thermal working fluid, provided from a temperature controlled fluid reservoir, through the channel in the heating assembly. The working fluid provides for heat to be exchanged between the reservoir and the dielectric lid.

The active heating structure (either the resistive heating wire or the thermal working fluid) portion of the heating assembly is transparent to the electromagnetic fields produced by the RF coil.

Voltage distribution or shielding functionality is provided by the electrically conductive structures incorporated into the heating assembly, thereby providing an integrated heater/voltage distribution of shielding assembly.

### BRIEF DESCRIPTION OF THE DRAWINGS

Additional objects and advantages of the present invention will be apparent in the following detailed description read in conjunction with the accompanying drawing figures.

FIG. 1 illustrates a conceptual diagram with a partial cross-sectional view of a wafer processing apparatus embodied according to the present invention.

FIG. 2 illustrates a plan view of a wiring pattern for a resistive heating element according to one embodiment of the present invention.

FIG. 3 illustrates a partial cut-away plan view of an electrical heating assembly according to an alternate embodiment of the present invention.

FIG. 4 illustrates a partial cut-away plan view of an electrical heating assembly according to another alternate embodiment of the present invention.

FIG. 5 illustrates a partial cut-away plan view of an electrical heating assembly according to a further alternate embodiment of the present invention.

FIG. 6 illustrates a partial cut-away plan view of a fluid heating assembly according to still another alternate embodiment of the present invention.

FIG. 7 illustrates a cross-sectional detail view of an electrical heating element, according to various embodiments of the present invention, disposed on a dielectric lid of a vacuum chamber.

FIG. 8 illustrates a cross-sectional detail view of a fluid heating element, according to various embodiments of the present invention, disposed on a dielectric lid of a vacuum chamber.

FIG. 9 illustrates a partial cut-away plan view of a fluid heating assembly according to a further alternate embodiment of the present invention.

FIG. 10 illustrates a cross-sectional detail view of a fluid heating element, according to the embodiment of FIG. 9, disposed on a dielectric lid of a vacuum chamber.

FIG. 11 illustrates a partial cross-sectional view of a wafer processing apparatus according to another alternate embodiment.

FIG. 12 illustrates a cross-sectional detail view of an electrical heating assembly, according to the embodiment of FIG. 11.

### DETAILED DESCRIPTION OF THE INVENTION

According to some embodiments, the present invention is embodied as a heating element, a voltage distribution electrode (including a Faraday shield), and a processing chamber in combination with one another. The heating element may be embodied using either fluid (as a conduit for a thermal working fluid to flow through) or electricity (as an electrical heating element).

According to other embodiments, the present invention is embodied as a temperature management apparatus for promoting thermal uniformity for a chamber wall using electricity. The apparatus includes a substrate and a resistive heating element. The substrate has a predetermined shape and has edges. The resistive heating element is disposed on the substrate adjacent to the edges of the substrate. The substrate is adapted to provide thermal communication between the resistive heating element and the chamber wall.

The predetermined shape is selected so as to promote even distribution of heat energy over the chamber wall. Preferably the predetermined shape has substantial radial symmetry. According to one embodiment, the substrate is shaped to have plural radial elements and a circular element, disposed at the periphery of the substrate, that joins the plural radial elements together. According to another embodiment, the substrate is shaped to have plural radial elements and a circular element, disposed near the center of the substrate, that joins the plural radial elements together. According to either of these embodiments, the circular elements employed are interrupted by at least one gap formed therein. Preferably the substrate is electrically conductive so that it forms a voltage distribution electrode.

According to another set of embodiments, the present invention is embodied as a temperature management apparatus for promoting thermal uniformity for a chamber wall using heated fluid. The apparatus includes a conduit and a thermal working fluid. The fluid conduit has a predetermined shape and has a substantially flattened cross section. The thermal working fluid is disposed in and flows through the fluid conduit.

According to a further embodiment, a resistive heating element is used as a heater, while a fluid flow is used for the thermal management, such as reducing transients caused by on/off cycling of the resistive element and/or removing heat from the lid when needed.

Certain optional features are advantageously used in conjunction with any of the electricity or heated fluid embodiments. Optionally, the apparatus may include a fan disposed near the resistive heating element so as to remove excess heat energy. Another feature that is optionally employed to enhance effectiveness of the invention is the combination of a temperature sensor and a temperature control circuit. The temperature sensor is adapted to be disposed in intimate contact with the chamber wall so as to generate a temperature signal indicative of the temperature of the chamber wall. The power control circuit is connected to receive the temperature signal as a feedback signal so as to provide a controlled amount of heat energy to the resistive heating element, or to the working fluid, as the case may be.

An apparatus for processing semiconductor wafers according to the present invention includes a vacuum chamber and a temperature management apparatus. The vacuum chamber is adapted to receive the semiconductor wafers therein, and has a chamber wall. The temperature management apparatus preferably includes both a heater and a fan (although the heater alone is sufficient). The heater is disposed outside of the vacuum chamber in thermal contact with the chamber wall. The fan is disposed near the heater to remove excess heat energy. Alternatively, the temperature management apparatus includes a controller operating a resistive heater in conjunction with working fluid channels.

Such an apparatus according to the present invention for processing semiconductor wafers also may include an RF coil and a voltage distribution electrode. The RF coil is disposed adjacent to the vacuum chamber so as to couple RF energy into the vacuum chamber. The heater is disposed between the RF coil and the chamber wall. The voltage distribution electrode is disposed between the heater and the chamber wall. Preferably, the heater is substantially electrically transparent to the RF energy coupled into the chamber.

Rather than a voltage distribution electrode, such an apparatus according to the present invention for processing a semiconductor wafer is optionally embodied with a Faraday shield having variable shielding efficiency. The Faraday shield is disposed between the heater and the dielectric wall.

A Faraday shield is generally understood in the art to be a layer or plate of conductive material disposed between the RF antenna and the lid of the chamber electrically connected (at least indirectly) to ground. A voltage distribution electrode is generally understood in the art to be a layer or plate of conductive material disposed between the RF antenna and the lid of the chamber, that is either connected to ground or is electrically floating. Thus, a voltage distribution electrode is considered to be a general concept that encompasses within its scope a Faraday shield, as well as other conductive electrodes regardless of how they relate to the system electrically.

According to alternate configurations, the dielectric wall is a flat lid, a dome-shaped lid, or another suitable geometry.

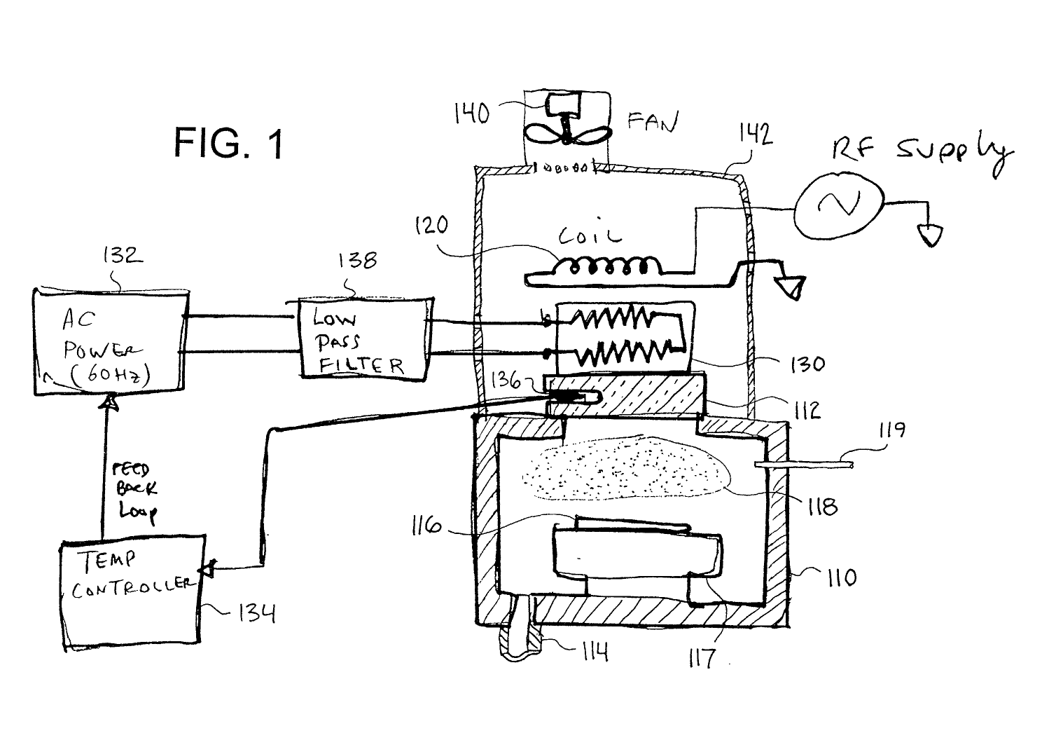

Referring to FIG. 1, a conceptual diagram with a partial cross-section view of a wafer processing apparatus embodied according to the present invention is illustrated. The vacuum chamber 110 has a dielectric lid 112. A pumping port 114 evacuates the chamber 110 to a pressure substantially below atmosphere (e.g., ˜10⁻⁴ torr). A semiconductor wafer 116 workpiece to be processed rests on a pedestal 117 that places the wafer 116 in a position so as to be exposed to a plasma cloud 118 of selected process gases introduced into the chamber via a process gas inlet 119.

A heating assembly 130 is placed between the RF coil 120 and the atmospheric side of the dielectric lid 112. The RF coil 120 couples energy into the vacuum chamber 110 to thereby excite the process gases inside the chamber into a plasma state so as to form the plasma cloud 118. Since it is advantageous to minimize the separation of the RF coil 120 and the dielectric lid 112 (for most efficient energy coupling), the heating assembly 130 is designed to conform well to the surface of the dielectric lid 112 and to be thin enough to not substantially increase the distance between the RF coil 120 and the lid 112, while at the same time, providing uniform and efficient heating of the dielectric surface.

The heating assembly 130 is provided with power from a variable duty cycle switched power supply 132. A command signal for selecting the duty cycle for how much AC power the power supply 132 provides is received from a temperature control circuit 134. A temperature sensor 136 that is embedded in the dielectric lid 112 provides feedback to the temperature control circuit 134.

A low pass filter 138 is electrically coupled to the heating assembly 130 to suppress any potential resonance in the heating assembly 130 with respect to the RF energy emanating from the RF coil 120.

A fan 140 provides forced air flow directed at the heating assembly 130 and the dielectric lid 112 to remove excess heat. The fan 140 is mounted on a housing 142 that surrounds the RF coil 120 and the heating assembly 130, and that rests on the top of the vacuum chamber 110.

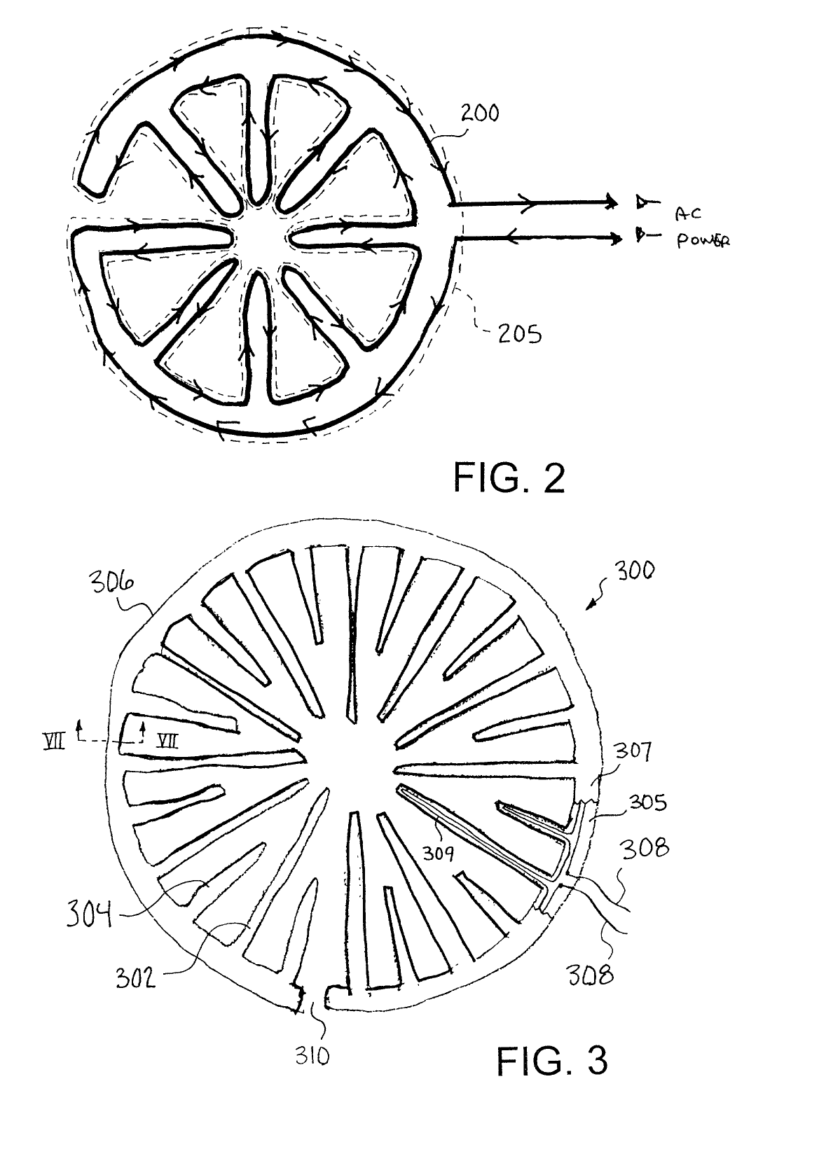

Referring to FIG. 2, a plan view of a wiring pattern for a resistive heating element according to one embodiment of the present invention is illustrated. A heating assembly according to the preferred embodiment of the present invention is adapted to fit a circularly-shaped lid that serves as the vacuum lid of a plasma processing vacuum chamber. This heating assembly is particularly useful for use in an inductively-coupled chambers having a dielectric lid. Accordingly, in much of the remaining description reference is made to a dielectric lid. However, it should be understood that the lid may also be used in other lids that are not made of a dielectric material.

A resistive heating element 200 follows a path on the circularly-shaped dielectric lid that provides for an even heating of the lid. The resistive heating element 200 rests atop substrate 205 that is shown in phantom. The arrowheads along the resistive heating element 200 illustrate flow of electricity. Preferably, the wiring pattern is embodied so as to have a continuous path that provides for current flow in both directions (i.e., both forward and back) along each of the radial segments and the connecting arcuate portions. The reason for the consistent juxtaposition of conductors with current flowing in opposite directions is so that their electromagnetic fields will cancel one another out.

Referring to FIG. 3, a partial cut-away plan view of an electrical heating assembly according to an alternate embodiment of the present invention is illustrated. One aspect of this heating assembly 300 is that the heating assembly is arranged on the surface of a dielectric lid in such a way that its elements are perpendicular to the direction of an electromagnetic field that is directed through the dielectric lid to generate a plasma cloud. Piecewise segments 302, 304 of the heating assembly 300 are arranged in a radial manner, connected together by a circular loop portion 306 having a diameter about the same as the dielectric lid. Electrical power is input via the power leads 308.

The partial cut-away portion of the view (in the lower right quadrant) shows the top layer of foam insulation 307 stripped away to expose the heater wire 309 resting on the substrate layer 305. The heater wire 309 is laid out along the piecewise segments 302, 304 and the circular loop portion 306 in an analogous fashion to the wiring pattern shown fully in FIG. 2.

The circular loop portion 306 preferably incorporates at least one gap 310 to provide an electric break. The purpose of the electrical break provided by the gap 310 is to prevent flow of an electric current in the heating assembly that would otherwise be induced by the electromagnetic field of the RF coil.

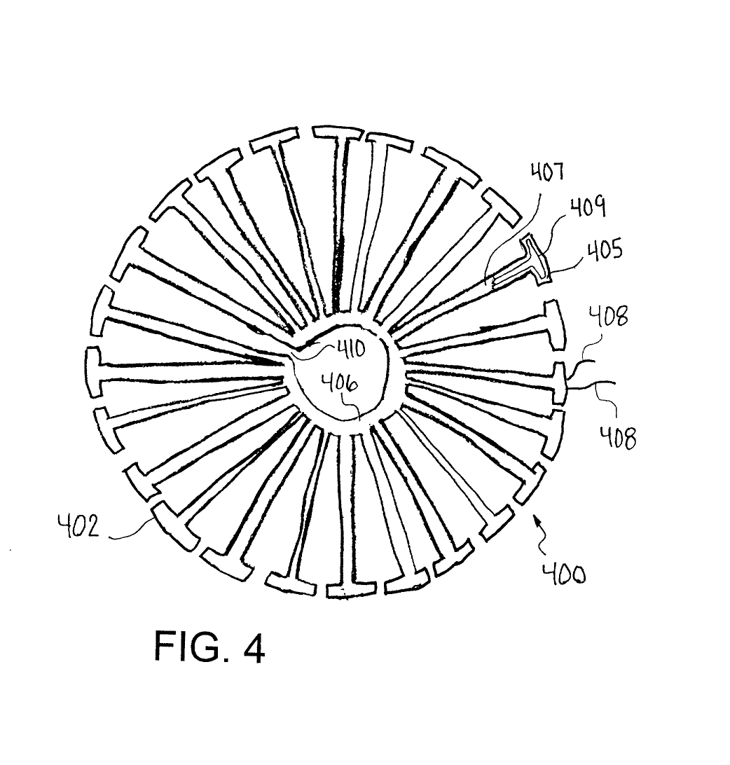

Referring to FIG. 4, a partial cut-away plan view of an electrical heating assembly according to another alternate embodiment of the present invention is illustrated. In this embodiment, the radially aligned piecewise segments 402 of the heating assembly 400 are connected together by a circular loop portion 406 that is much smaller than the diameter of the dielectric lid. Electrical power is input via the power leads 408. The circular loop 406 contains one or more gaps 410 to provide electric breaks that to prevent electromagnetically induced current from flowing in the heater assembly 400.

The partial cut-away portion of the view (in the upper right quadrant) shows the top layer of foam insulation 407 stripped away to expose the heater wire 409 resting on the bottom layer 405. The heater wire 409 is laid out along the circular loop portion and 406 the radially aligned piecewise segments 402 in an analogous fashion to the wiring pattern shown fully in FIG. 2.

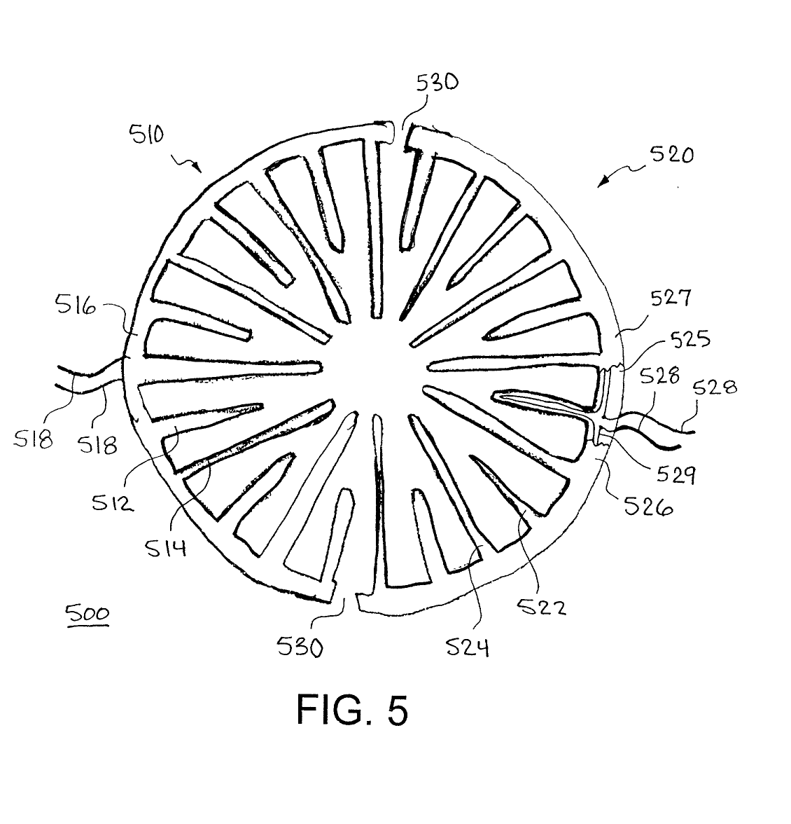

Referring to FIG. 5, a partial cut-away plan view of an electrical heating assembly according to a further alternate embodiment of the present invention is illustrated. In this embodiment, the heating assembly 500 is configured as a pair of semicircular halves 510, 520, which are separated from one another by gaps 530. Piecewise segments 512, 514 of the semicircular half 510 of the heating assembly 500 are arranged in a radial manner and are connected together by a semi-circular portion 516. Piecewise segments 522, 524 of the other semicircular half 520 of the heating assembly 500 are also arranged in a radial manner and are connected together by a semi-circular portion 526. Each of the semicircular halves 510, 520 has a radius of curvature about half the diameter of the dielectric lid. Electrical power is input via the power leads 518, 528.

The partial cut-away portion of the view (on the right side) shows the top layer of foam insulation 527 stripped away to expose the heater wire 529 resting on the bottom layer 525. The heater wire 529 is laid out along the piecewise segments 522, 524 and the semi-circular portion 526 in an analogous fashion to the wiring pattern shown fully in FIG. 2.

The spacing of the radial segments 512, 514, 522, 524 used in the heating assembly 500 is chosen to maintain a uniform temperature on the inner surface (i.e., vacuum side) of the dielectric lid. The spacing is preferably chosen so as to allow enough area between adjacent radial segments 512, 514, 522, 524 in order to remove excess heat from the dielectric lid outer surface (i.e., atmosphere side) by forced air conduction, while still achieving a uniform temperature on the inner surface due to the heat conduction within the dielectric lid.

It is not necessary that this embodiment use two separate heaters for the two halves. Indeed for sake of simplicity it is preferable to implement this embodiment with a single heater wire powered by a single supply and controlled by a single power controller. In the single heater implementation of the embodiment of FIG. 5, the heater wires simply bridge across the gaps 530, along with the foam top layer 527. Although this creates a closed loop heater wire, this is not a point of concern since the heater wire has a sufficiently high impedance so as to keep any RF field induced eddy currents to a negligible level.

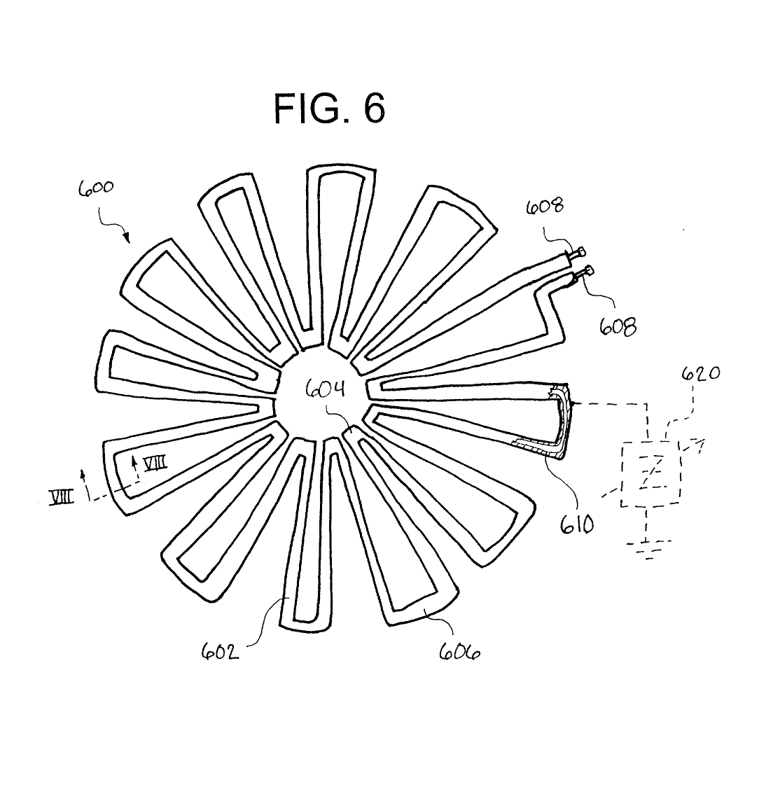

Referring to FIG. 6, a partial cut-away plan view of a fluid heating assembly according to still another alternate embodiment of the present invention is illustrated. The heating assembly 600 according to this embodiment incorporates a continuous fluid channel within the structure of the radial segments 602 and arcuate segments 604, 606 connecting the radial segments 602 together. Temperature control of the dielectric lid is achieved in this embodiment by forcing a thermal working fluid, provided from a temperature controlled fluid reservoir (via the fluid connections 608), through the channel in the heating assembly 600. The working fluid provides for heat to be exchanged between the reservoir and the lid. The partial cut-away portion of the view (on the right side) shows the fluid channel 610 that carries thermal working fluid the length of the heating assembly 600.

The fluid heating assembly may be embodied using varying geometry without departing from the scope of the invention. Any circular segments used to connect together radial segments will be provided with one or more gaps so that they do not form a full circle.

FIG. 6 also illustrates (in phantom) an aspect of the present invention that is optional for incorporation into any of the embodiments. The voltage distribution electrodes (i.e., heater assembly substrates) according the various embodiments are optionally connectable to ground through a variable impedance 620. The shielding properties of the voltage distribution electrode can be manipulated by varying the value of the variable impedance 620.

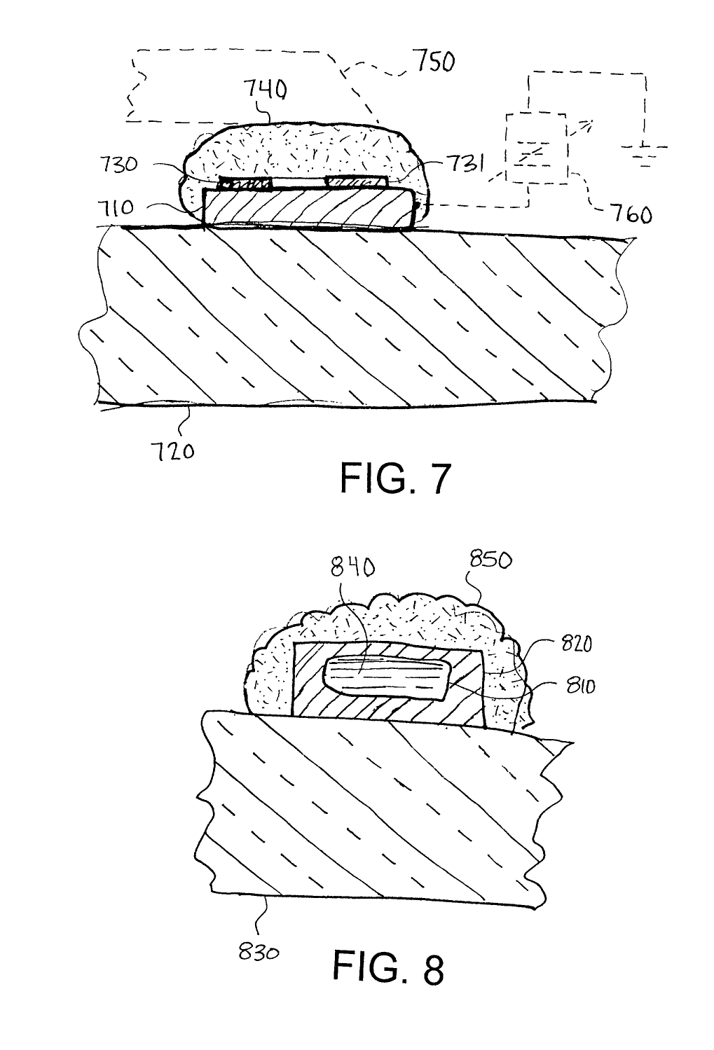

Referring to FIG. 7, a cross-sectional detail view of an electrical heating assembly, according to various embodiments of the present invention, disposed on a dielectric lid of a vacuum chamber is illustrated. The bottom layer 710 of the heating assembly according to the resistive heating embodiments is preferably constructed from anodized aluminum, but can be suitably constructed from any material that has good thermal conductivity (e.g., aluminum or copper). The bottom layer 710 is placed in direct contact with the dielectric lid 720 so as to provide good thermal communication therewith. The resistive heater wire segments 730, 731 (formed from material such as Nichrome wire) are attached to the bottom layer 710 without being electrically connected thereto and are wound along the radial segments and connective circular loop (refer to FIGS. 2 to 5) in a manner which maximizes the electromagnetic resistance (i.e., impedance) of the overall heater wire circuit to the electromagnetic fields produced by the coil. The heater supply current flows in opposite directions in the adjacent wire segments 730, 731. That is to say, the current flows into the page for one segment 730 and out of page for its adjacent segment 731, for example.

The heating elements according to the electrical embodiments are preferably operated using low frequency alternating current (50 to 60 Hz), so that the connection of a low pass filter with the resistive heater wire is sufficient to effectively prevent the RF energy of the coil from inducing current flow in the resistive heater wire.

A layer of thermal insulating material 740 (preferably foamed polymer) is placed on the surfaces of the heater wire 730 and may extend over the bottom layer 710. This insulating material layer 740 improves the efficiency of the heating assembly by minimizing heat losses to the ambient air. This insulation is particularly helpful for the embodiments that utilize forced air convection in order to remove excess heat from the outer (i.e., top) surface of the dielectric lid 720.

The electrical heating assembly is optionally secured to the lid 720 by a mechanical clamp 750 (shown in phantom) or is secured by an adhesive bond between the lid 720 and the bottom layer 710 by a heat conductive epoxy. If the RF coil is sufficiently heavy, then the weight of the RF coil alone, resting on the electrical heating assembly, can be used to secure the electrical heating assembly to the top of the lid 720.

Also shown in phantom is an optional variable impedance 760 connectable between the bottom layer 710 and ground potential. The shielding properties of the bottom layer 710 can be manipulated by varying the value of the variable impedance 760.

Referring to FIG. 8, a cross-sectional detail view of a fluid heating assembly, according to various embodiments of the present invention, disposed on a dielectric lid of a vacuum chamber is illustrated. The heating assembly incorporates a fluid channel 810 within the structure of the radial segments and the connecting arcuate segments of a conductive conduit 820. Temperature control of the dielectric lid 830 is achieved in this embodiment by forcing a thermal working fluid 840, provided from a temperature controlled fluid reservoir, through the channel 810 in the heating assembly. The working fluid 840 provides for heat to be exchanged between the reservoir and the dielectric lid 830. A layer of thermal insulating material 850 is placed on the surfaces of the conductive conduit 820. This insulating material layer 850 improves the efficiency of the heating assembly by minimizing heat losses to the ambient air.

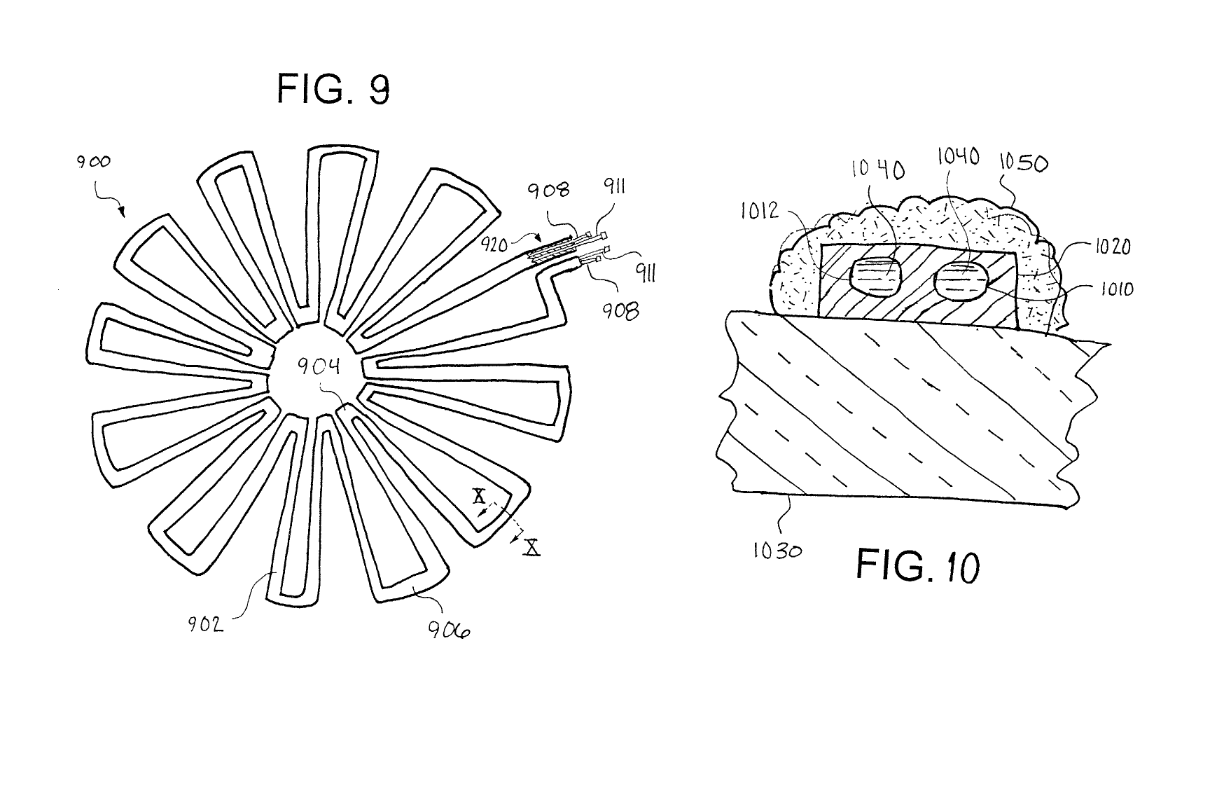

Referring to FIG. 9, a partial cut-away plan view of a fluid heating assembly according to a further alternate embodiment of the present invention is illustrated. The heating assembly 900 according to this embodiment incorporates a pair of continuous fluid channels within the structure of the radial segments 902 and arcuate segments 904, 906 connecting the radial segments 902 together. Temperature control of the dielectric lid is achieved in this embodiment by forcing a thermal working fluid in a first direction through the outer channel (via the fluid connections 908), and in a second direction through the inner channel (via the fluid connections 911) in the heating assembly 900. The working fluid is supplied from a temperature controlled reservoir and provides for heat to be exchanged between the reservoir and the dielectric lid. The partial cut-away portion of the view (in the upper right quadrant) shows the dual (inner and outer) fluid channels that carry thermal working fluid (in opposite directions) the length of the heating assembly 900.

Referring to FIG. 10, a cross-sectional detail view of a fluid heating element, according to the embodiment of FIG. 9, is illustrated. The heating assembly incorporates an inner fluid channel 1010 and an outer fluid channel 1012 in tandem with one another within the structure of the radial segments and the connecting arcuate segments of a conductive conduit 1020. Temperature control of the dielectric lid 1030 is achieved in this embodiment by forcing a thermal working fluid 1040, provided from a temperature controlled fluid reservoir, in a first direction through the inner channel 1010 and in an opposite direction through the outer channel 1012. The working fluid 1040 provides for heat to be exchanged between the reservoir and the dielectric lid 1030.

The primary advantage of this embodiment compared to the other fluid embodiment (see FIGS. 6 and 8) is that it provides better temperature uniformity over the surface of the chamber lid. By running fluid in opposite directions, the temperature gradient of the working fluid in the conduits cancels out. The trade off, though, is that the dual channel embodiment is more complex to implement.

A layer of thermal insulating material 1050 is placed on the surfaces of the conductive conduit 1020. This insulating material layer 1050 improves the efficiency of the heating assembly by minimizing heat losses to the ambient air.

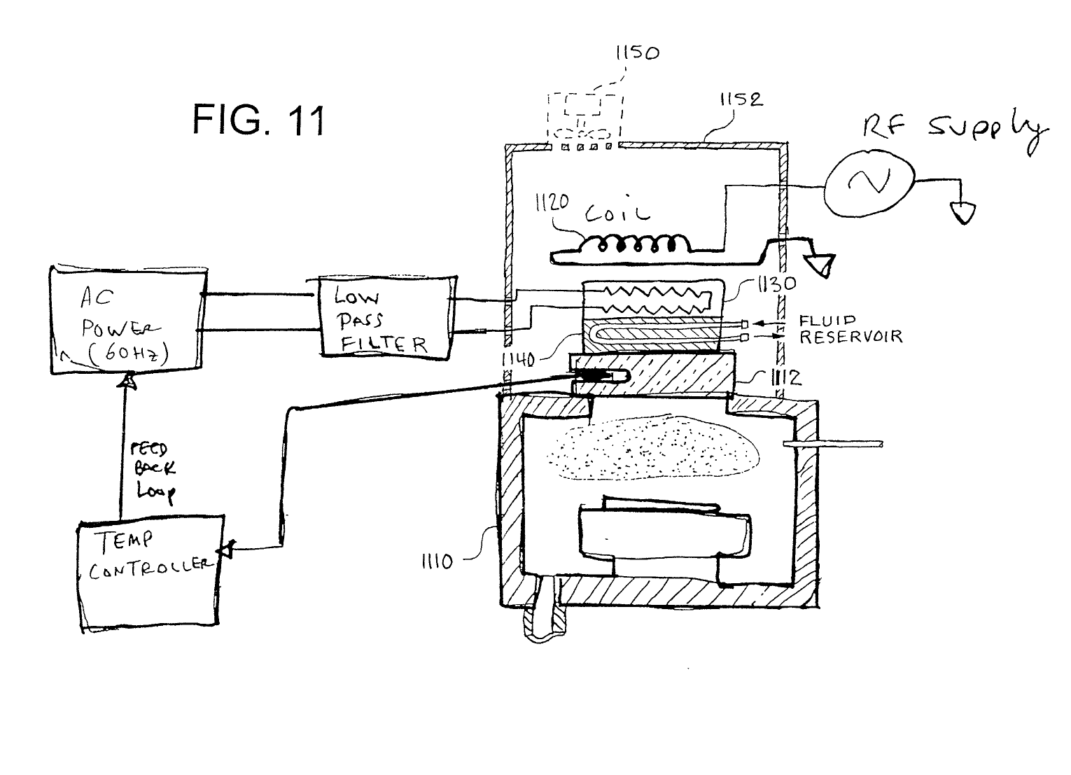

Referring to FIG. 11, a conceptual diagram with a partial cross-sectional view of a wafer processing apparatus according to another alternate embodiment is illustrated. The vacuum chamber 1110 has a dielectric lid 1112. A wafer is processed inside the chamber 1110 by a plasma cloud adjacent the lid 1112. Refer to the description of FIG. 1 for a more detailed explanation of the functionality inside the chamber.

In this alternate embodiment, a heating assembly (a heating element 1130 in combination with a conductive substrate 1140) is placed between the RF coil 1120 and the atmospheric side of the dielectric lid 1112. The RF coil 1120 couples energy into the vacuum chamber 1110 to thereby excite the process gases inside the chamber into a plasma state. The heating assembly according to this embodiment includes a conductive substrate 1140 that is disposed between the lid 1112 and the electrical heating element portion 1130 of the heating assembly. The conductive substrate 1140 has one or more fluid conduits formed therein to convey thermal working fluid to and from a temperature regulated fluid reservoir. The conductive substrate 1140 is either permitted to float, or is optionally connected to ground via a variable impedance.

The heating element 1130 is provided with electrical power from a variable duty cycle switched power supply, which receives feedback loop commands from a temperature controller that monitors a temperature sensor at the lid 1112. The operation of this thermal control loop is analogous to that described with respect to FIG. 1. Resonance of RF energy in the heating assembly is suppressed by a low pass filter.

Optionally, a fan 1150 provides forced air flow directed at the heating assembly and the dielectric lid 1112 to remove excess heat. The fan 1150 is mounted on a housing 1152 that surrounds the RF coil 1120 and the heating assembly, and that rests on the top of the vacuum chamber 1110.

The heating assembly (which is shown only conceptually in FIG. 11) is advantageously embodied so as to have the general shape (in plan view) of the heating assembly shown in any of FIGS. 2-6 and 9. The cross-sectional view, though, is substantially different.

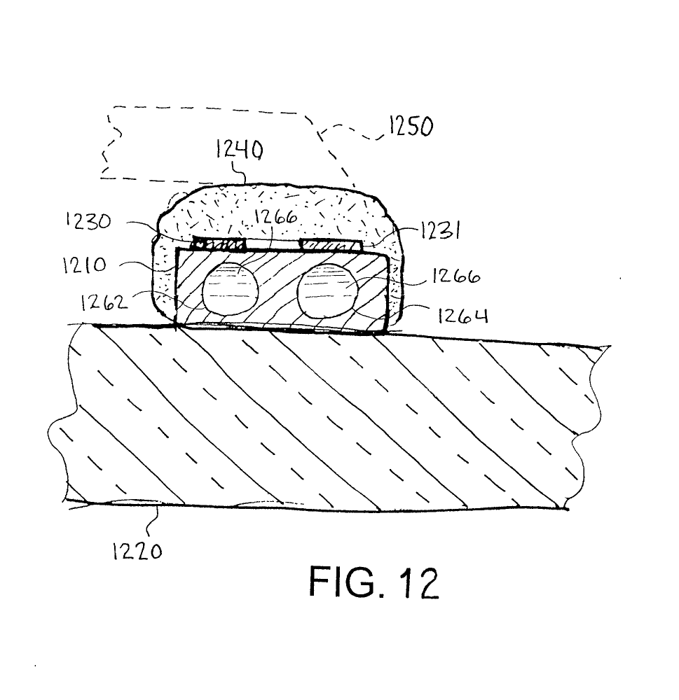

Referring to FIG. 12, a cross-sectional detail view of an electrical heating assembly, according to the embodiment of FIG. 11 is illustrated. The conductive bottom layer (or substrate) 1210 is placed in direct contact with the dielectric lid 1120 so as to provide good thermal communication therewith. The resistive heater wire segments 1230, 1231 are attached to the bottom layer 1210 without being electrically connected thereto and are wound along the radial segments and connective circular loop (refer to FIGS. 2 to 5) in a manner which maximizes the electromagnetic resistance (i.e., impedance) of the overall heater wire circuit to the electromagnetic fields produced by the coil. The heater supply current flows in opposite directions in the adjacent wire segments 1230, 1231.

The heating assembly incorporates a pair of fluid channels 1262, 1264 in tandem with one another within the structure of the radial segments and the connecting arcuate segments of the conductive bottom layer 1210. A thermal working fluid 1266, provided from a temperature controlled fluid reservoir, is forced in a first direction through one fluid channel 1262 and in an opposite direction through the adjacent channel 1264. The working fluid 1266 provides for heat to be exchanged between the reservoir and the dielectric lid 1220.

A layer of thermal insulating material 1240 is placed on the surfaces of the heater wire segments 1230, 1231 and may extend over the bottom layer 1210. This insulating material layer 1240 improves the efficiency of the heating assembly by minimizing heat losses to the ambient air. This insulation is particularly helpful for the embodiments that utilize forced air convection in order to remove excess heat from the outer (i.e., top) surface of the dielectric lid 1220.

The electrical heating assembly is optionally secured to the lid 1220 by a mechanical clamp 1250 (shown in phantom) or is secured by an adhesive bond between the lid 1220 and the bottom layer 1210 by a heat conductive epoxy.

The embodiment illustrated by FIGS. 11 and 12 has plural operational modes. In a first operational mode, the working fluid is heated in the fluid reservoir to a temperature above ambient and functions to smooth out thermal transients. Thermal transients arise due to the sudden step changes caused when the electrical heating element is energized and de-energized or when the fan 1150 is turned on and off (if the fan is incorporated). The constant flow of heated fluid in the channels 1262, 1264 of the conductive bottom layer 1210 serves as a stabilizing influence.

According to a second operational mode, the working fluid is cooled in the fluid reservoir so that it may serve as a mechanism for removing heat from the lid 1220. In this operational mode the conductive bottom layer 1210 itself serves as a cooling device in place of the fan 1150.

Of course, in the case of either of these operating modes, the conductive bottom layer 1210 continues to function to distribute electric potential evenly across the lid 1220 and, when grounded, to act as a shield.

Another feature of the invention is that it maintains a more uniform electromagnetic potential across the dielectric lid. The bottom layer of the heating assembly (alternatively, the conductive conduit in the fluid embodiments) forms a voltage distribution electrode that develops an electromagnetic potential that is approximately equal to the spatially average potential determined over the entire area defined by the heating assembly. Thus, although the active heating structure (either the resistive heating wire or the thermal working fluid) portion of the heating assembly is transparent to the electromagnetic fields produced by the coil that penetrate the dielectric lid and generate the plasma, the conductive portion of the heating assembly takes on the role of shaping the electric potential produced by the coil. The result of this averaging is the minimization of detrimental effects of electromagnetic potentials that are too high (e.g., sputtering of the dielectric by the plasma) and of electromagnetic potentials that are too low (e.g., heavy byproduct depositions on the dielectric lid). The simultaneous control of both the temperature of the dielectric lid and the electrostatic potential in the region directly adjacent to the lid produces conditions that are very favorable for achieving the desired plasma process results on the workpiece.

Although the description has consistently referred to the chamber lid as being made from a dielectric, this is simply a non-limiting example of how the present invention may be implemented. Certainly the present invention is applicable in the context of semiconductor processing chambers having lids and walls made of any conductive or nonconductive materials.

The present invention has been described in terms of preferred embodiments, however, it will be appreciated that various modifications and improvements may be made to the described embodiments without departing from the scope of the invention.

What is claimed is:

1. In combination, a heating element, a voltage distribution electrode, and a semiconductor processing chamber, the semiconductor processing chamber comprising:
a wafer support disposed inside the chamber,
a gas delivery channel disposed in the chamber to deliver gas adjacent the wafer support, and
a chamber wall, the chamber wall being in thermal contact with the heating element;
wherein the voltage distribution electrode is disposed adjacent the chamber wall.

2. The combination of claim 1, wherein the heating element is an electrical heating element.

3. The combination of claim 1, wherein the heating element comprises:
a conduit, and
a thermal working fluid flowing through the conduit.

4. The combination of claim 1, wherein the voltage distribution electrode has a circular shape.

5. The combination of claim 4, wherein the voltage distribution electrode comprises:
a circular loop; and
radial segments connected together by the circular loop.

6. A temperature management apparatus for promoting thermal uniformity for a chamber wall, the apparatus comprising:
a substrate having a predetermined shape and having edges;
a resistive heating element disposed on the substrate adjacent to the edges of the substrate;
wherein the substrate is adapted to provide thermal communication with the chamber wall.

7. The temperature management apparatus of claim 6, wherein the predetermined shape promotes even distribution of heat energy over the chamber wall.

8. The temperature management apparatus of claim 6, further comprising:
a source of air flow disposed near the chamber wall so as to remove excess heat energy.

9. The temperature management apparatus of claim 8, where the source of air flow comprises a fan.

10. The temperature management apparatus of claim 6, further comprising:
a temperature sensor adapted to be disposed in intimate contact with the chamber wall so as to generate a temperature signal indicative of the temperature of the chamber wall; and
a power control circuit connected to receive the temperature signal as a feedback signal so as to provide a controlled amount of power dissipated by the resistive heating element.

11. The temperature management apparatus of claim 10, wherein the power dissipated by the resistive heating element is controlled so as to be at a minimum level when plasma is energized near the chamber wall, and to be at a maximum level when no plasma is energized near the chamber wall.

12. The temperature management apparatus of claim 11, wherein the minimum level corresponds to substantially no power dissipation.

13. The temperature management apparatus of claim 6, wherein the predetermined shape is substantially radially symmetric.

14. The temperature management apparatus of claim 13, wherein the predetermined shape comprises plural radial elements and a circular element, disposed at the periphery of the substrate, joining the plural radial elements together.

15. The temperature management apparatus of claim 14, wherein at least one gap is formed in the circular element.

16. The temperature management apparatus of claim 15, wherein at least two gaps are formed in the circular element, the gaps being arranged substantially symmetrically.

17. The temperature management apparatus of claim 13, wherein the predetermined shape comprises plural radial elements and a circular element, disposed near the center of the substrate, joining the plural radial elements together.

18. The temperature management apparatus of claim 17, wherein at least one gap is formed in the circular element.

19. The temperature management apparatus of claim 6, wherein the substrate is electrically conductive and forms a voltage distribution electrode.

20. The temperature management apparatus of claim 6, wherein the resistive heating element comprises: plural resistive segments arranged such that spatially adjacent ones of the plural resistive segments have electrical current flowing in opposite directions.

21. The temperature management apparatus of claim 20, wherein the plural resistive segments are electrically connected in series with one another.

22. A temperature management apparatus for promoting thermal uniformity for a chamber wall, the apparatus comprising:
a fluid conduit having a predetermined shape and having a substantially flattened cross section; and
a thermal working fluid disposed in and flowing through the fluid conduit.

23. The temperature management apparatus of claim 22, wherein the predetermined shape promotes even distribution of heat energy over the chamber wall.

24. The temperature management apparatus of claim 22, wherein the predetermined shape is substantially radially symmetric.

25. The temperature management apparatus of claim 22, further comprising:
a source of air flow disposed near the chamber wall so as to remove excess heat energy.

26. The temperature management apparatus of claim 25, where the source of air flow comprises a fan.

27. The temperature management apparatus of claim 22, where the thermal working fluid is provided via connection to a temperature controlled reservoir.

28. An apparatus for processing a semiconductor wafer comprising:
a vacuum chamber adapted to receive the semiconductor wafer therein, the vacuum chamber having a chamber wall; and
a temperature management apparatus comprising:
a heater disposed outside of the vacuum chamber in thermal contact with the chamber wall, and
a source of air flow disposed near the dielectric wall to remove excess heat energy.

29. The apparatus for processing a semiconductor wafer of claim 28, further comprising:
an RF coil disposed adjacent to the vacuum chamber so as to couple RF energy into the vacuum chamber, the heater being disposed between the RF coil and the chamber wall; and
a voltage distribution electrode disposed between the heater and the chamber wall.

30. The apparatus for processing a semiconductor wafer of claim 29, wherein the heater is substantially electrically transparent to the RF energy coupled into the chamber.

31. The apparatus for processing a semiconductor wafer of claim 29, wherein the heater does not substantially hinder generation of plasma in the chamber by the RF energy coupled into the chamber.

32. The apparatus for processing a semiconductor wafer of claim 28, further comprising:
an RF coil disposed adjacent to the vacuum chamber so as to couple RF energy into the vacuum chamber, the heater being disposed between the RF coil and the chamber wall; and
a Faraday shield having variable shielding efficiency, the shield being disposed between the heater and the chamber wall.

33. The apparatus for processing a semiconductor wafer of claim 32, wherein the heater is substantially electrically transparent to the RF energy coupled into the chamber.

34. The apparatus for processing a semiconductor wafer of claim 28, wherein the chamber wall is a flat lid.

35. The apparatus for processing a semiconductor wafer of claim 28, wherein the chamber wall is a dome-shaped lid.

36. The apparatus for processing a semiconductor wafer of claim 28, wherein the chamber wall is a hemispherical shaped lid.

37. The apparatus for processing a semiconductor wafer of claim 28, wherein source of air flow comprises a fan.

38. The apparatus for processing a semiconductor wafer of claim 28, wherein the heater is in physical contact with the chamber wall.
